(19) United States
(12) Patent Application Publication
(10) Pub. No.: US 2023/0327547 A1
(43) Pub. Date: Oct. 12, 2023

(54) DC-DC CONVERTER, AND DC OUTPUT DEVICE

(71) Applicant: SHANGHAI RUNHOOD POWER CO., LTD., SHANGHAI (CN)

(72) Inventors: XIAODONG WANG, SHANGHAI (CN); ZHONGSHU CHEN, SHANGHAI (CN); WEI QIN, SHANGHAI (CN)

(21) Appl. No.: 18/054,548

(22) Filed: Nov. 11, 2022

(30) Foreign Application Priority Data
Apr. 6, 2022 (CN) 202220831457.7

(51) Int. Cl. H02M 3/00; H02J 7/00

(52) U.S. Cl. CPC H02M 3/003; H02J 7/0042; H02J 2207/20

(57) ABSTRACT

Embodiments of the present disclosure provide a DC-DC converter, and a DC output device. The DC-DC converter includes: a housing; a detachable connection structure arranged on the housing and configured to detachably connect with a battery module; a DC-DC conversion module received in the housing and configured to convert a direct current input from the battery module to a direct current at a preset voltage; and one or more current output ports arranged on the housing, the one or more current output ports are electrically connected with the DC-DC conversion module and are configured to output the direct current at the preset voltage obtained from the DC-DC conversion module.

### CROSS REFERENCE TO RELATED APPLICATIONS

The present application claims the benefit of priority under the Paris Convention to Chinese Patent Application No. 202220831457.7 filed on Apr. 6, 2022, which is incorporated herein by reference in its entirety.

### TECHNICAL FIELD

Embodiments of the present disclosure relate to the field of portable power source technology, in particular to a direct current to direct current (DC-DC) converter, and DC output device.

### BACKGROUND

The portable power sources meet people's requirements for electricity in outdoor activities, and offer conveniences to users in some emergency situations. With an increasing energy storage level, the portable power sources are more and more favored by consumers.

The inventor found that the portable power sources in the prior art have at least problems of large sizes, heavy weights and non-portabilities.

### SUMMARY

Embodiments of the present disclosure aim to provide a DC-DC converter, and a DC output device, which can improve portability of portable power sources.

To this end, some embodiments of the present disclosure provide a DC-DC converter, including: a housing; a detachable connection structure arranged on the housing and configured to detachably connect with a battery module; a DC-DC conversion module received in the housing and configured to convert a direct current input from the battery module to a direct current at a preset voltage; and one or more current output ports arranged on the housing, the one or more current output ports are electrically connected with the DC-DC conversion module and are configured to output the direct current at the preset voltage obtained from the DC-DC conversion module.

Some embodiments of the present disclosure further provide a DC output device, including a battery module and the above-mentioned DC-DC converter, a connector of the DC-DC converter is electrically connected with a plug of the battery module.

The DC-DC converter according to the present disclosure includes a housing, a detachable connection structure, a DC-DC conversion module and one or more current output ports. The detachable connection structure is arranged on the housing and configured to detachably connect with a battery module. The DC-DC conversion module is received in the housing and configured to convert a direct current input from the battery module to a direct current at a preset voltage. The one or more current output ports are arranged on the housing, and the one or more current output ports are electrically connected with the DC-DC conversion module and are configured to output the direct current at the preset voltage obtained from the DC-DC conversion module. By providing an individually detachable DC-DC converter, a DC output can be obtained by connecting the DC-DC converter and the battery module. Compared with the integrated product incorporating DC, AC, and battery functions in the related art, the DC-DC converter according to the present disclosure can overcome problems of large sizes and heavy weights of the integrated product in a case that only the DC function but no AC function is needed, and is more convenient to carry. Moreover, when the battery module is in a state of low-power or out of operation, only replacement of a full-power battery module or that having good performance is needed, without having to replace the entire DC output device. In this way, the DC-DC converter according to the present disclosure is convenient to use and has a low cost.

In some examples, the detachable connection structure includes a clasp member configured to form a lock with a groove defined on the battery module by fastening with the groove. In this way, the fastness of the connection between the DC-DC converter and the battery module can be ensured.

In some examples, the clasp member includes a limiting block fixed on an inner wall of the housing, a resilient part fixed on the limiting block, and a hook connected to a free end of the resilient part and configured to be stuck in the groove of the battery module by pressing or stretching the resilient part. In this way, the problem that the clasp member is liable to be damaged by multiple uses can be avoided, and the service life of the clasp member can be improved.

In some examples, the clasp member further includes a button connected with the hook, the DC-DC converter further includes a through groove passing through the housing, and the button is exposed on an outer surface of the housing via the through groove. In this way, the DC-DC converter can be connected with the battery module by pressing the button to push inward the clasp member, thereby avoiding the damage on the clasp member due to the squeezing resulted from directly sticking the clasp member into the groove of the battery module, and improving the service life of the clasp member.

In some examples, the detachable connection structure includes a groove configured to form a lock with a clasp member arranged on the battery module.

In some examples, an annular flange is arranged on an edge of the housing, and the annular flange is configured to fasten with an inner wall of a connection slot arranged on the battery module, to form a physical connection between the DC-DC converter and the battery module; or the edge of the housing extends outward to form a connection slot, the connection slot is configured to fasten with a periphery of an annular flange arranged on the battery module, to form the physical connection between the DC-DC converter and the battery module. With the cooperation of the annular flange and the connection slot, the physical connection and positioning between the DC-DC converter and the battery module can be achieved. In this way, the connection between the DC-DC converter and the battery module can be more accurate and convenient.

In some examples, the DC-DC converter includes at least two current output ports, at least one of which is a charging and discharging port that has both discharge function and charge function. In this way, when the battery module is in a low-power state but no spare battery module is available, an external DC power supply can be connected to the charging and discharging port to charge the battery module.

In some examples, the DC-DC converter further includes a front panel arranged on the housing, the one or more current output ports are arranged on the front panel, and a bump for mistake proofing is arranged at an edge of the front panel. With the bump for mistake proofing, a mistake in an installation direction of the front panel can be avoided.

In some examples, the DC-DC conversion module includes a first circuit board and a second circuit board connected to each other via an electric wire harness.

### BRIEF DESCRIPTION OF THE DRAWINGS

FIG. 1 is a perspective structural schematic diagram at a viewing angle of the DC-DC converter according to some embodiments of the present disclosure.

FIG. 2 is a perspective structural schematic diagram at another viewing angle of the DC-DC converter according to some embodiments of the present disclosure.

FIG. 3 is an explosive view of the DC-DC converter according to some embodiments of the present disclosure.

FIG. 4 is a structural schematic diagram of the DC output device with the DC-DC converter being detached from the battery module according to some embodiments of the present disclosure.

FIG. 5 is a perspective structural schematic diagram of the battery module according to some embodiments of the present disclosure.

### DETAILED DESCRIPTION OF THE EMBODIMENTS

In order to make the purposes, technical solutions and advantages of the embodiments of the present disclosure more clear, the embodiments of the present disclosure will be described in detail below in reference to the accompanying drawings. Those skilled in the art should understand that in the embodiments of the present disclosure, many technical details are proposed to enable readers to better understand the present disclosure. However, even without these technical details and various changes and modifications based on the following embodiments, the technical solution claimed in the present disclosure can be realized.

In the embodiments of the present disclosure, the terms such as “up”, “down”, “left”, “right”, “front”, “rear”, “top”, “bottom”, “inside”, “outside”, “middle”, “vertical”, “horizontal”, “transverse”, “longitudinal” or the like those indicate orientation or position relationships are based on the orientation or position relationships as shown in the drawings. These terms are mainly used to better describe the present disclosure and its embodiments, but not to define that the corresponding device, element or component must have a specific orientation, or be constructed and operated in a specific orientation.

In addition, some of the above terms can have other meanings besides the orientation or position relationships. For example, the term “up” may also be used to define an attachment or connection relationship in some cases. For those skilled in the art, the specific meanings of these terms in the present disclosure should be interpreted according to specific situations.

Moreover, the terms such as “installation”, “arrangement”, “providing with”, “opening”, “connection” and “inter-connection” should be interpreted broadly. For example, it may be a fixed connection, a detachable connection, or an integral structure; or it may be a mechanical connection or an electrical connection; or it may be a direct connection, or an indirect connection via an intermediate media, or an internal communication between two devices, elements or components. For those skilled in the art, the specific meanings of these terms in the present disclosure should be interpreted according to specific situations.

Furthermore, the terms “first”, “second” or the like are mainly used to distinguish different devices, elements or components (of the same or different types and structures), but not to indicate or imply the relative importance and quantity of the corresponding devices, elements or components. Unless otherwise specified, “a plurality of” means two or more.

The inventor found that the existing products are designed as integrated products incorporating battery, DC, and AC functions for use or sale. In a case that only the DC function but no the AC function is needed, the AC function will become a burden, and the product will have an increased size, making it inconvenient to carry.

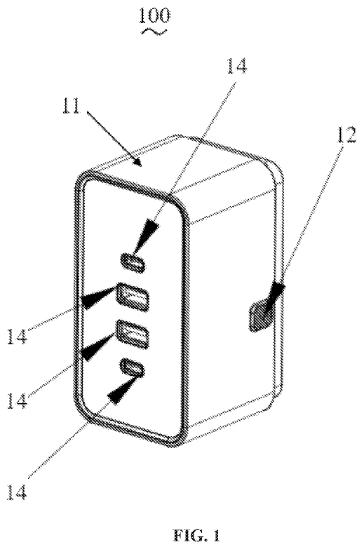

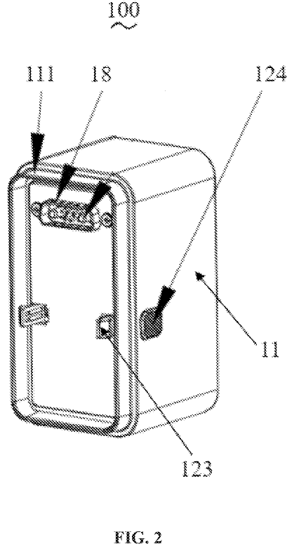

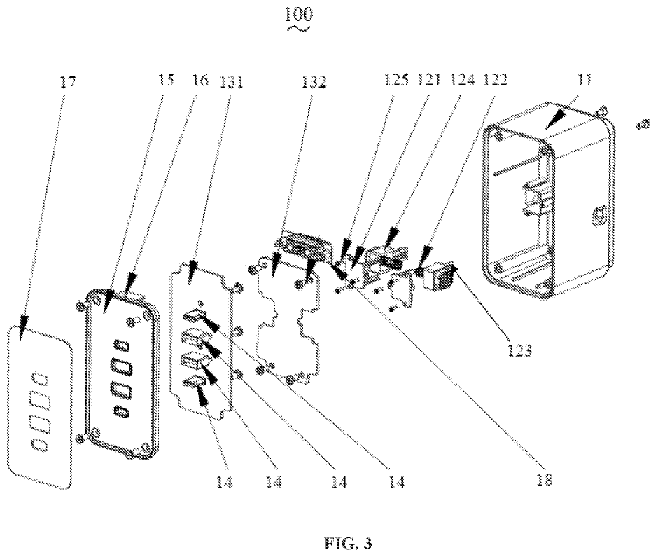

Some embodiments of the present disclosure provide a DC-DC converter 100, as shown in FIGS. 1 to 3, including a housing 11, a detachable connection structure, a DC-DC conversion module 13 and one or more current output ports 14. The detachable connection structure is arranged on the housing 11 and configured to detachably connect with a battery module 200. The DC-DC conversion module 13 is received in the housing 11 and configured to convert a direct current input from the battery module 200 to a direct current at a preset voltage. The one or more current output ports 14 are arranged on the housing 11, and the one or more current output ports 14 are electrically connected with the DC-DC conversion module 13 and are configured to output the direct current at the preset voltage obtained from the DC-DC conversion module 13.

The battery module 200 may be a modular product of lithium battery modules with battery management system (BMS), and the DC-DC converter 100 may also be called as a DC-DC output module.

In some embodiments, the detachable connection structure includes a clasp member 12 configured to form a lock with a groove defined on the battery module 200 by fastening with the groove. In this way, the fastness of the connection between the DC-DC converter 100 and the battery module 200 can be ensured, and the construction of the detachable connection structure can be simplified, thereby reducing the manufacturing complexity of the DC-DC converter 100.

In some embodiments, the clasp member 12 includes a limiting block 121 fixed on an inner wall of the housing 11, a resilient part 122 fixed on the limiting block 121, and a hook 123 connected to a free end of the resilient part 122 and configured to be stuck in the groove of the battery module 200 by pressing or stretching the resilient part 122. In this way, the problem that the clasp member 12 is liable to be damaged by multiple uses can be avoided, and the service life of the clasp member can be improved. The limiting block 121 may be fixed on the inner wall of the housing 11 by a screw 125.

In some embodiments, the resilient part 122 may be an elastic part, such as a spring, silica gel, foam or the like, as long as it can elastically deform under the action of the hook 123, and can restore without the action of the hook 123 and reposition the hook 123, embodiments of the present disclosure are not limited to this.

In some embodiments, the clasp member 12 further includes a button 124 connected with the hook 123, the DC-DC converter 100 further includes a through groove passing through the housing 11, and the button 124 is exposed on an outer surface of the housing 11 via the through groove. In this way, the DC-DC converter 100 can be connected with the battery module 200 by pressing the button 124 to push inward the clasp member 12, thereby avoiding the damage on the clasp member 12 due to the squeezing resulted from directly sticking the clasp member 12 into the groove of the battery module 200, and improving the service life of the clasp member 12. When the DC-DC converter 100 is to be detached from the battery module 200, the button 124 is pressed, such that the hook 123 compresses the resilient part 122 and detaches from the battery module 200. In this way, the DC-DC converter 100 can be detached quickly, thereby simplifying the detachment operation of the DC-DC converter 100 and improving the user experience.

In some embodiments, a number of the clasp members 12 is two. The two clasp members 12 are arranged on the housing 11 opposite to each other, and each correspond to a groove. In this way, fastness of the connection between the DC-DC converter 100 and the battery module 200 can be improved. In some other embodiments, there are a plurality of clasp members 12 arranged on the housing at intervals.

In some embodiments, the detachable connection structure includes a groove configured to form a lock with a clasp member 12 arranged on the battery module 200. The structure of the clasp member 12 of the battery module 200 is similar to that as mentioned above and will not be repeated here. Accordingly, a number of the clasp members 12 is two. The two clasp members 12 are arranged on the housing 11 opposite to each other, and each correspond to a groove. In this way, fastness of the connection between the DC-DC converter 100 and the battery module 200 can be improved.

In practice, the detachable connection structure also may include an interlocking structure or a detachable connection structure of other types, as long as it can implement the quick connection and detachment between the DC-DC converter 100 and the battery module 200, embodiments of the present disclosure are not limited to this.

In some embodiments, an annular flange 111 is arranged on an edge of the housing 11, and the annular flange 111 is configured to fasten with an inner wall of a connection slot arranged on the battery module 200, to form a physical connection between the DC-DC converter 100 and the battery module 200; or the edge of the housing 11 extends outward to form a connection slot, the connection slot is configured to fasten with a periphery of an annular flange 111 arranged on the battery module 200, to form the physical connection between the DC-DC converter 100 and the battery module 200. With the cooperation of the annular flange 111 and the connection slot, the physical connection and positioning between the DC-DC converter 100 and the battery module 200 can be achieved. In this way, the connection between the DC-DC converter 100 and the battery module 200 can be more accurate and convenient.

In other words, the DC-DC converter 100 cooperates with the battery module 200. When in use, the DC-DC converter 100 is connected to the battery module 200. For example, in the above-mentioned embodiments, the physical connection can be formed by aligning the annular flange 111 of the DC-DC converter 100 with the connection slot of the battery module 200, and then pushing the annular flange into the connection slot. Following the physical connection, the clasp member 12 of the DC-DC converter 100 and the groove of the battery module 200 form a lock to prevent a detachment when in use. In addition, the DC-DC conversion module 13 of the DC-DC converter 100 is connected with a plug of the battery module 200, to form the electrical connection between the DC-DC converter 100 and the battery module 200. The physical connection also can be formed by pressing the button 124, to avoid the risk of damaging the clasp member 12 due to directly sticking the clasp member into the groove.

In some embodiments, the DC-DC converter includes at least two current output ports 14, at least one of which is a charging and discharging port (INOUT) that has both discharge function and charge function. In this way, when the battery module 200 is in a low-power state but no spare battery module 200 is available, an external DC power supply can be connected to the charging and discharging port to charge the battery module 200. In an example, there may be four current output ports 14, including three discharging ports and one charging and discharging port.

It is noted that the charge via the charging and discharging port brings no influence to the discharge via other current output ports 14. In this way, DC output and charging can be carried out simultaneously, in other words, the charging does not affect the DC output.

In some embodiments, the DC-DC converter 100 further includes a front panel 15 arranged on the housing 11, the one or more current output ports 14 are arranged on the front panel 15, and a bump 16 for mistake proofing is arranged at an edge of the front panel 15. In other words, the front panel 15 is used to be attached with the input and output ports of an external device. With the bump 16 for mistake proofing, a mistake in an installation direction of the front panel 15 can be avoided. The front panel 15 and the housing 11 together form a receiving space, to receive the DC-DC conversion module 13 in the receiving space. In this way, the internal elements including the DC-DC conversion module 13 can be protected.

When in use, a surface of the front panel 15 away from the receiving space may be affixed with a decorative plate 17. The text or pattern descriptions on the decorative plate 17 are used to indicate and mark the four current output ports 14 on the front panel 15, so as to introduce the functions and corresponding parameters of the current output ports 14. In this way, users can select and use the desired ports as needed.

In some embodiments, the DC-DC conversion module 13 (e.g., an internal circuit board) is mainly used to convert the voltage and current from the battery module 200 into specific voltage and current, and output them through the four current output ports 14. In addition, the internal circuit board has protection and alarm functions against for example overload, short circuit, overvoltage, undervoltage, overtemperature or the like. In this way, users can use the product safely and conveniently. Moreover, the internal circuit board can be provided with a connector 18 connected with the battery module 200 to implement the functions of current input or output and communication.

In some embodiments, the DC-DC conversion module 13 (e.g., an internal circuit board) includes a first circuit board 131 and a second circuit board 132 connected to each other via an electric wire harness. In an example, the first circuit board 131 is fixed to the front panel 15 by a screw or the clasp member 12, the decorative plate 17 is affixed on the front panel 15, and the second circuit board 132 is fixed in the housing 11 by a first fixing screw. The connecter 18 is fixed on the housing 11 by a second fixing screw.

In some embodiments, the housing 11 is made of plastic or metal (for example, aluminum alloy) to support and protect the internal circuit, and to fix or connect with the front panel 15, the internal circuit and the current output ports 14. The housing 11 can also be made of other materials, as long as the obtained housing 11 has enough strength and waterproof and heat-resistant properties to a certain extent, so that the DC-DC converter 100 can work normally. The embodiments of the present disclosure are not limited to this.

It should be understood that the connection modes between the components of the DC-DC converter 100 may include screw connection, snap-fit, gluing, riveting or other connection modes, as long as the components can be firmly combined and the DC-DC converter 100 can function normally. The embodiments of the present disclosure are not limited to this.

The present disclosure provides an individually detachable DC-DC converter 100, and a DC output can be obtained by connecting the DC-DC converter 100 with the battery module 200. Compared with the integrated product incorporating DC, AC, and battery functions in the related art, the DC-DC converter according to the present disclosure can overcome problems of large sizes and heavy weights of the integrated product in a case that only the DC function but no AC function is needed, and is more convenient to carry. Moreover, when the battery module 200 is in a state of low-power or out of operation, only replacement of a full-power battery module 200 or that having good performance is needed, without having to replace the entire DC output device. In this way, the DC-DC converter according to the present disclosure is convenient to use and has a low cost.

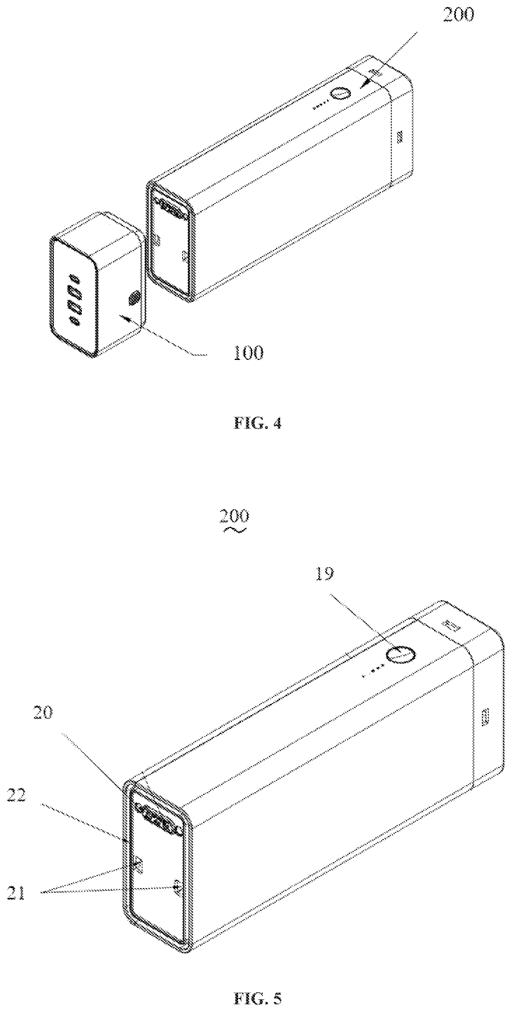

Some embodiments of the present disclosure provide a DC output device, as shown in FIGS. 4 and 5, including a battery module 200 and the above-mentioned DC-DC converter 100, a connector of the DC-DC converter 100 is electrically connected with a plug 20 of the battery module 200.

It is noted that the battery module 200 is detachably connected with the DC-DC converter 100. In some embodiments, one of the DC-DC converter 100 and the battery module 200 includes a clasp member, and the other includes a groove. For example, the DC-DC converter 100 may include the clasp member, and the battery module 200 may include the groove 21.

In some embodiments, one of the DC-DC converter 100 and the battery module 200 includes an annular flange, and the other includes a connection slot. For example, the battery module 200 may include the connection slot 22, an inner wall of which is fastened with the annular flange of the DC-DC converter 100, in order to form a physical connection between the DC-DC converter 100 and the battery module 200.

In some embodiments, the battery module 200 includes a power button 19 (that is, an on/off button). The DC output can be obtained by pressing the power button 19. After use, the battery module 200 and the DC-DC converter 100 can be shut down by long pressing the power button 19.

It should be understood that the embodiments of the DC output device can make technical effects similar to those of the embodiments of the DC-DC converter, and will not be repeated here.

Since the embodiments of the DC-DC converter correspond to the embodiments of the DC output device, these embodiments can be implemented in coordination. The relevant technical details mentioned in the embodiments of the DC-DC converter are applicable to the embodiments of the DC output device, and the technical effects that can be achieved in the embodiments of the DC-DC converter can also be achieved in the embodiments of the DC output device, and will not be repeated here to reduce repetition. Accordingly, the relevant technical details mentioned in the embodiments of the DC output device can also be applied in the embodiments of the DC-DC converter.

Those skilled in the art should understand that the above embodiments are merely specific examples of the present disclosure, and in practical applications, various changes can be made in form and detail without departing from the spirit and scope of the present disclosure.

What is claimed is:

1. A direct current to direct current (DC-DC) converter, comprising:
a housing;
a detachable connection structure arranged on the housing and configured to detachably connect with a battery module;
a DC-DC conversion module received in the housing and configured to convert a direct current input from the battery module to a direct current at a preset voltage; and
one or more current output ports arranged on the housing, wherein the one or more current output ports are electrically connected with the DC-DC conversion module and are configured to output the direct current at the preset voltage.

2. The DC-DC converter according to claim 1, wherein the detachable connection structure comprises a clasp member configured to form a lock with a groove defined on the battery module by fastening with the groove.

3. The DC-DC converter according to claim 2, wherein the clasp member comprises a limiting block fixed on an inner wall of the housing, a resilient part fixed on the limiting block, and a hook connected to a free end of the resilient part and configured to be stuck in the groove of the battery module by pressing or stretching the resilient part.

4. The DC-DC converter according to claim 3, wherein the clasp member further comprises a button connected with the hook, and the DC-DC converter further comprises a through groove passing through the housing, wherein the button is exposed on an outer surface of the housing via the through groove.

5. The DC-DC converter according to claim 1, wherein the detachable connection structure comprises a groove configured to form a lock with a clasp member arranged on the battery module.

6. The DC-DC converter according to claim 1, wherein an annular flange is arranged on an edge of the housing, and the annular flange is configured to fasten with an inner wall of a connection slot arranged on the battery module, to form a physical connection between the DC-DC converter and the battery module; or
the edge of the housing extends outward to form a connection slot, wherein the connection slot is configured to fasten with a periphery of an annular flange arranged on the battery module, to form the physical connection between the DC-DC converter and the battery module.

7. The DC-DC converter according to claim 1, comprising at least two current output ports, at least one of which is a charging and discharging port that has both discharge function and charge function.

8. The DC-DC converter according to claim 1, further comprising a front panel arranged on the housing, wherein the one or more current output ports are arranged on the front panel, and a bump for mistake proofing is arranged at an edge of the front panel.

9. The DC-DC converter according to claim 1, wherein the DC-DC conversion module comprises a first circuit board and a second circuit board connected to each other via an electric wire harness.

10. A direct current (DC) output device, comprising a battery module and a direct current to direct current (DC-DC) converter;
wherein a connector of the DC-DC converter is electrically connected with a plug of the battery module;
wherein the DC-DC converter comprise:
a housing;
a detachable connection structure arranged on the housing and configured to detachably connect with a battery module;
a DC-DC conversion module received in the housing and configured to convert a direct current input from the battery module to a direct current at a preset voltage; and
one or more current output ports arranged on the housing, wherein the one or more current output ports are electrically connected with the DC-DC conversion module and are configured to output the direct current at the preset voltage.

11. The DC output device according to claim 10, wherein the detachable connection structure comprises a clasp member configured to form a lock with a groove defined on the battery module by fastening with the groove.

12. The DC output device according to claim 11, wherein the clasp member comprises a limiting block fixed on an inner wall of the housing, a resilient part fixed on the limiting block, and a hook connected to a free end of the resilient part and configured to be stuck in the groove of the battery module by pressing or stretching the resilient part.

13. The DC output device according to claim 12, wherein the clasp member further comprises a button connected with the hook, and the DC-DC converter further comprises a through groove passing through the housing, wherein the button is exposed on an outer surface of the housing via the through groove.

14. The DC output device according to claim 10, wherein the detachable connection structure comprises a groove configured to form a lock with a clasp member arranged on the battery module.

15. The DC output device according to claim 10, wherein an annular flange is arranged on an edge of the housing, and the annular flange is configured to fasten with an inner wall of a connection slot arranged on the battery module, to form a physical connection between the DC-DC converter and the battery module; or
the edge of the housing extends outward to form a connection slot, wherein the connection slot is configured to fasten with a periphery of an annular flange arranged on the battery module, to form the physical connection between the DC-DC converter and the battery module.

16. The DC output device according to claim 10, wherein the DC-DC converter comprises at least two current output ports, at least one of which is a charging and discharging port that has both discharge function and charge function.

17. The DC output device according to claim 10, wherein the DC-DC converter further comprises a front panel arranged on the housing, wherein the one or more current output ports are arranged on the front panel, and a bump for mistake proofing is arranged at an edge of the front panel.

18. The DC output device according to claim 10, wherein the DC-DC conversion module comprises a first circuit board and a second circuit board connected to each other via an electric wire harness.
